(19) United States
(12) Patent Application Publication
(10) Pub. No.: US 2025/0046716 A1
(43) Pub. Date: Feb. 6, 2025

(54) MODIFIED REVERSE SELECTIVE BARRIER STRUCTURE

(71) Applicant: QUALCOMM Incorporated, San Diego, CA (US)

(72) Inventors: Junjing BAO, San Diego, CA (US); John Jianhong ZHU, San Diego, CA (US); Giridhar NALLAPATI, San Diego, CA (US)

(21) Appl. No.: 18/365,791

(22) Filed: Aug. 4, 2023

(51) Int. Cl. H01L 23/532; H01L 21/768; H01L 23/522

(52) U.S. Cl. CPC H01L 23/53238; H01L 21/76814; H01L 21/7684; H01L 21/76846; H01L 21/76877; H01L 23/5226; H01L 23/53266

(57) ABSTRACT

A via with a modified reverse selective barrier structure and method for making the same are disclosed. In an aspect, a via structure comprises a first metal structure providing an electrical conductor (e.g., copper) oriented vertically; a second structure (e.g., cobalt) surrounding and in contact with a bottom and sides of the first metal structure; a third structure (e.g., metallic tantalum) surrounding and in contact with a bottom and sides of the second structure; a fourth structure (e.g., ruthenium) disposed beneath and in contact with a bottom of the third structure; and a fifth structure (e.g., amorphous tantalum nitride) surrounding and in contact with sides of the third structure; wherein a bottom surface of the fourth structure is in contact with a top surface of a metallization layer. In some aspects, the fifth structure is also surrounding and in contact with sides of the fourth structure.

### BACKGROUND OF THE DISCLOSURE

### 1. Field of the Disclosure

This disclosure relates generally to semiconductor wafer process, and more specifically to a modified reverse selective barrier structure and methods for making the same.

### 2. Description of the Related Art

Integrated circuit (IC) technology has achieved great strides in advancing computing power through miniaturization of electrical components. An IC device may be implemented in the form of an IC chip that has a set of circuits integrated thereon, including a plurality of active and passive components (e.g., transistors, diodes, capacitors, inductors, and/or resistors) and layers of contacts and interconnects above the active and passive components. As wafer process features sizes get smaller, the resistance of via structures tends to increase, which can have a negative impact on performance and/or speed of the ID device. Damascene processes use intermediate materials, which may be referred to as “liners,” interposed between the metal used for signals and vias, e.g., copper (Cu), and other substances, e.g., oxides, to prevent migration of metal ions into the other substances. These materials, which may be referred to as “barriers,” may be chosen for their ability to prevent such migration, even though their resistivity is higher than would be preferred. The use of these barrier materials also increases the resistance of vias and other structures.

Accordingly, in order to reduce the resistance of vias and other structures, there is a need for better barrier structures that contribute less resistance than do conventional barrier structures.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a via structure includes a first metal structure providing an electrical conductor oriented vertically; a second structure surrounding and in contact with a bottom and sides of the first metal structure; a third structure surrounding and in contact with a bottom and sides of the second structure; a fourth structure disposed beneath and in contact with a bottom of the third structure; and a fifth structure surrounding and in contact with sides of the third structure, wherein a bottom surface of the fourth structure is in contact with a top surface of a metallization layer disposed below the via structure.

In an aspect, a method of fabricating a via structure includes forming a via hole by etching down through a first layer of a first material to expose a portion of a top surface of a metal conductor below the first layer; forming a self-assembled monolayer (SAM) on the portion of the top surface of the metal conductor; forming a tantalum nitride (TaN) layer on side walls of the via hole; removing the SAM from the portion of the top surface of the metal conductor; depositing a layer of a second material onto the portion of the top surface of the metal conductor; depositing a layer of a third material onto a top surface of the layer of the second material and onto the side walls of the via hole to form a first structure having an inside surface; depositing a layer of a fourth material onto the inside surface of the first structure to form a second structure having an inside surface; and depositing a layer of a fifth material onto the inside surface of the second structure and filling a volume created by the inside surface of the second structure.

In an aspect, a method of fabricating a via structure includes forming a via hole by etching down through a first layer of a first material to expose a portion of a top surface of a metal conductor below the first layer; depositing a layer of a second material onto the portion of the top surface of the metal conductor; forming a SAM on a top surface of the layer of the second material; forming a TaN layer on side walls of the via hole; removing the SAM from the top surface of the layer of the second material; depositing a layer of a third material onto the top surface of the layer of the second material and onto the side walls of the via hole to form a first structure having an inside surface; depositing a layer of a fourth material onto the inside surface of the first structure to form a second structure having an inside surface; and depositing a layer of a fifth material onto the inside surface of the second structure and filling a volume created by the inside surface of the second structure.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings, wherein like reference numbers represent like parts, which are presented solely for illustration and not limitation of the disclosure.

FIG. 1 is a cross-sectional view of a conventional via with a reverse selective barrier structure.

FIG. 2 is a cross-sectional view of an improved via with a modified reverse selective barrier structure according to aspects of the disclosure.

FIGS. 3A-3H are cross-sections that illustrate steps in a process for fabricating an improved via with a modified reverse selective barrier structure according to aspects of the disclosure.

FIG. 4 is a flowchart of an example process associated with fabrication of an improved via with a modified reverse selective barrier structure according to aspects of the disclosure.

FIG. 5 is a cross-sectional view of an improved via with a modified reverse selective barrier structure according to aspects of the disclosure.

FIGS. 6A-6H are cross-sections that illustrate steps in a process for fabricating an improved via with a modified reverse selective barrier structure according to aspects of the disclosure.

FIG. 7 is a flowchart of an example process associated with fabrication of an improved via with a modified reverse selective barrier structure according to aspects of the disclosure.

FIG. 8 illustrates a mobile device in accordance with some examples of the disclosure.

FIG. 9 illustrates various electronic devices that may be integrated with any of the aforementioned integrated devices or semiconductor device in accordance with various examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

Various aspects relate generally to an integrated circuit (IC) device and a manufacturing method of making the integrated circuit device. Some aspects more specifically relate to an improved via with a modified reverse selective barrier structure, and a method for making the same, according to aspects of the disclosure. In an aspect, a via structure comprises a first metal structure providing an electrical conductor (e.g., copper) oriented vertically; a second structure (e.g., cobalt, ruthenium, etc.) surrounding and in contact with a bottom and sides of the first metal structure; a third structure (e.g., metallic tantalum) surrounding and in contact with a bottom and sides of the second structure; a fourth structure (e.g., ruthenium, molybdenum, osmium, iridium, rhodium, etc.) disposed beneath and in contact with a bottom of the third structure; and a fifth structure (e.g., amorphous tantalum nitride) surrounding and in contact with the sides of the third structure; wherein a bottom surface of the fourth structure is in contact with a top surface of a metallization layer (e.g., copper). In some aspects, the fifth structure is also surrounding and in contact with the sides of the fourth structure.

Particular aspects of the subject matter described in this disclosure can be implemented to realize one or more of the following potential advantages. The improved via has good adhesion to copper metallization layers even at small feature sizes and has a lower via resistance compared to conventional reverse selective barrier metal via designs. The lower via resistance enables higher maximum operating frequencies for an IC device using the improved vias compared to the same IC device using conventional vias.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage, or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

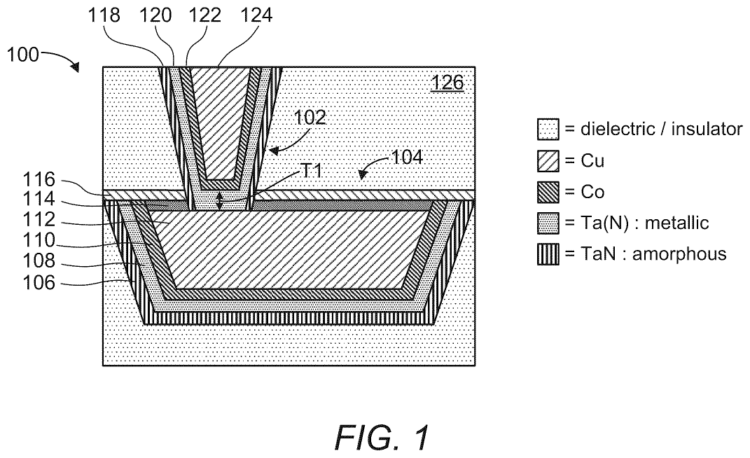

FIG. 1 is a cross-sectional view 100 of a conventional via with a reverse selective barrier structure. FIG. 1 illustrates a detail of a semiconductor integrated circuit (IC) device, showing a via 102 connected to a metal trace 104. As shown in FIG. 1, the metal trace 104 follows a channel lined with an amorphous tantalum nitride (TaN) layer 106, which was deposited using an atomic layer deposition (ALD) process, typically to a thickness of ˜1 nm. Because the TaN layer 106 created by an ALD process is amorphous it has a high resistivity compared to metallic tantalum, e.g., 5-10 times higher than metallic tantalum.

The TaN layer 106 is lined with a tantalum (Ta) layer that has traces of TaN and is therefore referred to herein as the Ta(N) layer 108. The Ta(N) layer 108 is deposited using a physical vapor deposition (PVD) process, typically to a thickness of ˜1 nm. The Ta(N) layer 108 is metallic and has a low resistivity compared to the TaN layer 106, but a high resistivity compared to metals. (The PVD process actually just deposits metallic Ta, but since the Ta is being deposited within TaN-lined trenches, some of the TaN will get intermingled with the Ta being deposited.)

Upon the Ta(N) layer 108 is deposited a liner 110 such as cobalt (Co). The liner 110 is deposited using a chemical vapor deposition (CVD) process, typically to a thickness of ˜2.5 nm. Finally, the liner 110 is filled with copper (Cu) to form a copper structure 112, which is the primary conductor of the metal trace 104. A metal cap 114 is selectively deposited onto the top surface of the copper structure 112. In some aspects, the metal cap 114 comprises cobalt. A dielectric etch stop layer 116 covers the metal cap 114 as well as the top surfaces of the TaN layer 106, the Ta(N) layer 108, and the liner 110. In some aspects, the dielectric etch stop layer 116 comprises silicon carbon nitride (SiCN).

As shown in FIG. 1, the via 102 has a similar construction, i.e., within the via opening over the copper structure 112, an amorphous TaN layer 118 is deposed on the sidewalls only via an ALD process, typically to a thickness of ˜1 nm. A Ta(N) layer 120 is then deposited on the sides and bottom using a PVD process, usually to a thickness of 1 nm in order to guarantee good adhesion and to avoid delamination, separation, or other interface problems. This thickness is labeled in FIG. 1 as T1. A liner 122 is then deposited on the sides and bottom using a CVD process, typically to a thickness of 2.5 nm. The structure is then filled with copper 124. In the example in FIG. 1, the via 102 and the metal trace 104 are enclosed by (or are structures within) a dielectric layer 126.

One problem with the conventional via shown in FIG. 1 is that the resistivity of the Ta(N) layer 120 (13˜240μΩ cm) is relatively high compared to the liner 122 (5μΩ cm) and the copper 124 (<1 μΩ cm). Thus, the resistivity of the Ta(N) layer 120 at 100 μΩ cm may be 20 times larger than the resistivity of the liner 122 and 100 times larger than the resistivity of the copper 124. Because of the thickness T1 required to provide good adhesion of the via 102 to the metal trace 104, the Ta(N) layer 120 contributes a non-negligible (and unwanted) resistance to the conventional via 102.

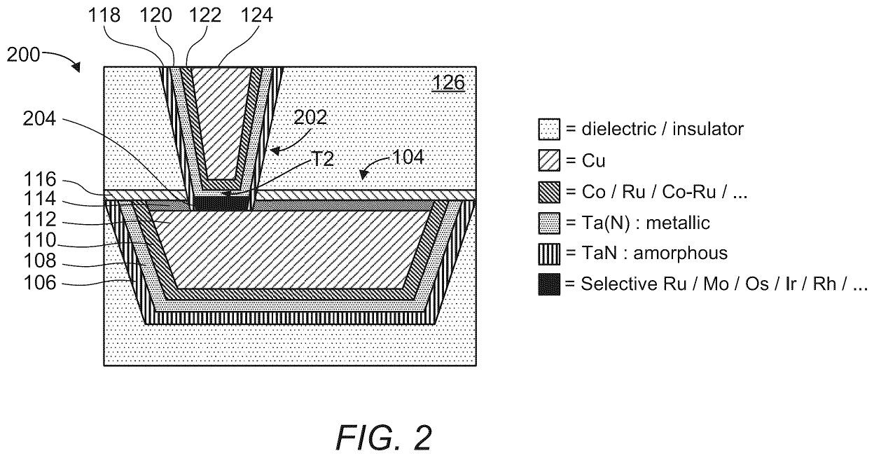

FIG. 2 is a cross-sectional view 200 of an improved via with a modified reverse selective barrier structure according to aspects of the disclosure. As can be seen in FIG. 2, the improved via 202 differs from the conventional via 102 in that an additional metal layer 204 is disposed between, and provides an electrical connection between, the copper structure 112 and the metallic Ta(N) layer 120. In some aspects, the metal layer 204 comprises at least one of ruthenium (Ru), molybdenum (Mo), osmium (Os), iridium (Ir), or rhodium (Rh). This metal layer 204 provides good adhesion and allows the Ta(N) layer 120 to be thinner (e.g., 0.5-0.7 nm for the via 202 versus 1.0 nm for the via 102), which reduces the resistance of the via 202.

Ruthenium, for example, provides good adhesion to copper and is known to have good reliability, which results in better process reliability. The other elements (Mo, Os, Ir, and Rh) have bulk resistivities that are similar to cobalt (i.e., between 4 and 10 μΩ cm) and have melting temperatures between that of cobalt and that of tungsten, which makes them compatible with existing wafer processes. These elements provide the additional benefit that they are stable in contact with silicon dioxide (SiO₂) and may thus allow for barrierless metallization. As will be explained in more detail below, in some aspects, the additional metal layer 204 may be fabricated using a “selective metal” process.

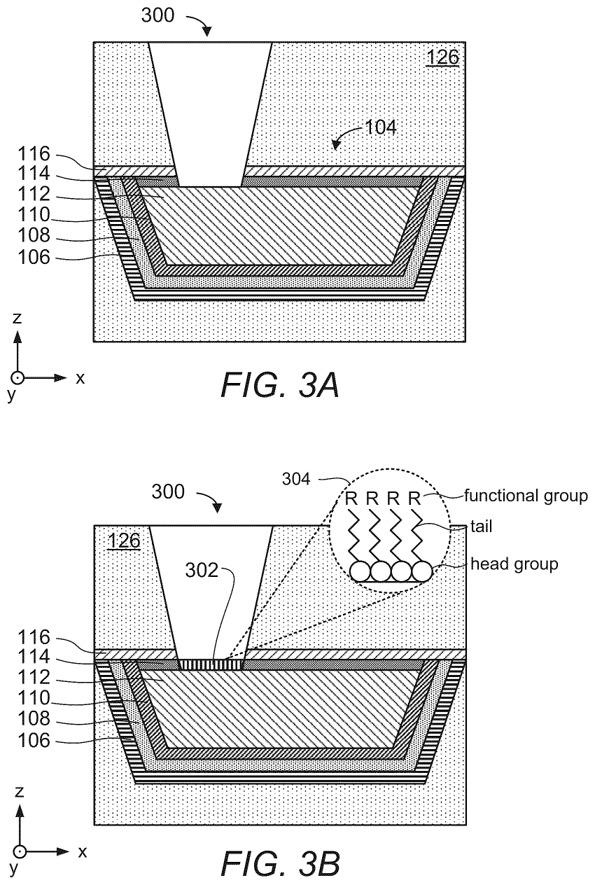

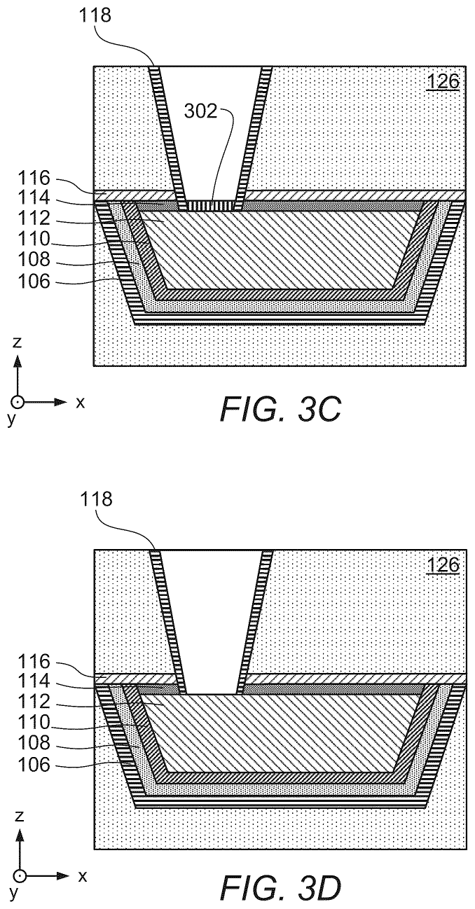

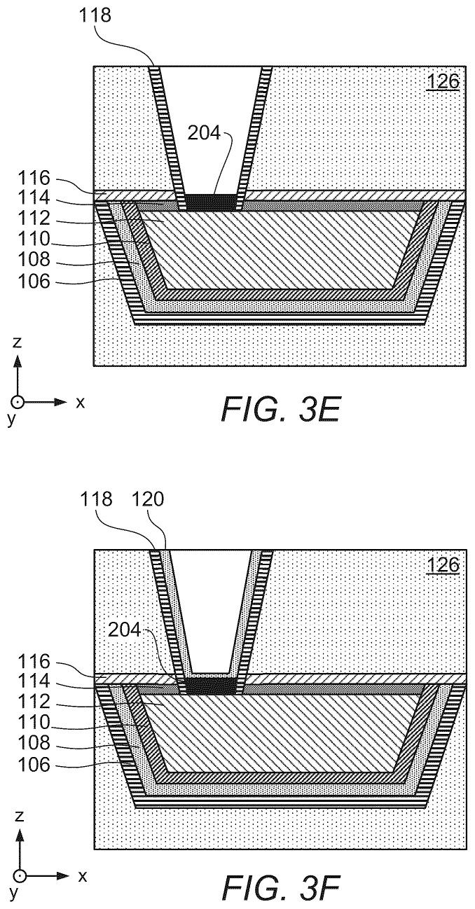

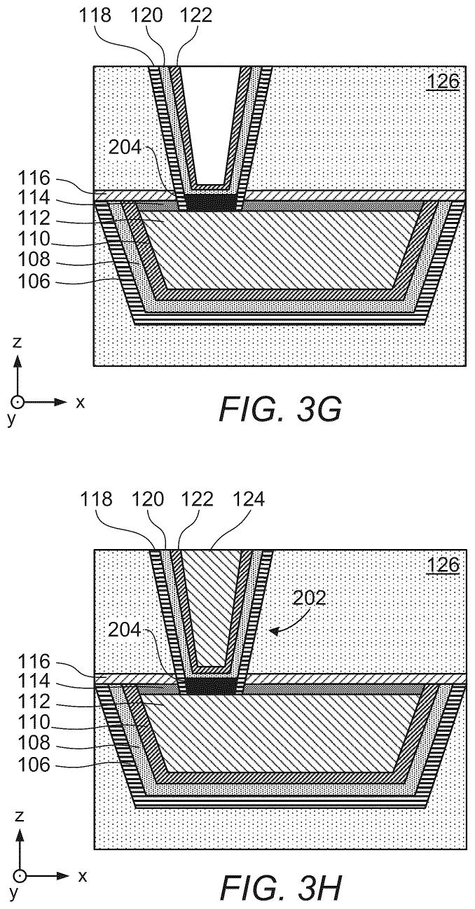

FIGS. 3A-3H are cross-sections that illustrate steps in a process for fabricating an improved via with a modified reverse selective barrier structure according to aspects of the disclosure. As shown in FIG. 3A, the process starts with a semiconductor structure comprising a metal trace 104. In the examples shown in FIGS. 3A-3H, the metal trace 104 is substantially similar to the like-numbered element in FIG. 1 and FIG. 2, and so the descriptions of the like-numbered components (e.g., 106, 108, 110, 112, 114, 116, etc.) will not be repeated here.

FIG. 3A illustrates the result after an etching process that produces a via hole 300 that exposes the copper structure 112. In some aspects, this process is part of a dual damascene trench/via patterning up to the step that removes the Co cap and exposes the Cu.

FIG. 3B illustrates the result after forming a self-assembled monolayer (SAM) 302 on the exposed portion of the copper structure 112. As shown in the magnified view 304, a SAM is a repeated series of molecules having a head group, shown as a circle, a long tail, and a functional group that is represented by the letter “R”. The head group may be formed by selective growth through chemisorption (e.g., sulfur to metallic contacts). The long tail may comprise alkanethiols with a (C—C)ⁿ chain. The functional group R provides a chemical inhibition to ALD. The SAM 302 may be deposited by electroless deposition (ELD) or PVD.

FIG. 3C illustrates the result after an ALD process that deposits TaN on the sidewalls of the via hole 300 to produce the TaN layer 118. In some aspects, the ALD process causes the TaN layer 118 to encroach upon and/or displace some of the SAM 302 adjacent to the TaN layer 118.

FIG. 3D illustrates the result after a process to remove the SAM 302, e.g., via H2/N2 (plasma) ash or thermal desorption.

In some aspects, because the TaN layer 118 has encroached upon and/or displaced portions of the SAM 302 adjacent to the TaN layer 118, the TaN layer 118 extends all the way down the sidewall of the via hole 300 to the copper structure 112.

FIG. 3E illustrates the result after a selective deposit of a metal layer 204 only onto the exposed portion of the copper structure 112 (and not onto TaN layer 118). In some aspects, the thickness of the additional metal layer 204 is between 1 nm and 10 nm. In some aspects, the additional metal layer 204 comprises at least one of Ru, Mo, Os, Ir, or Rh. In some aspects, the resistivity of the additional metal layer 204 is less than 10 μΩ cm. In some aspects, the resistivity of the additional metal layer 204 is approximately 7.1 μΩ cm.

FIG. 3F illustrates the result after a PVD deposition of Ta, resulting in a Ta(N) layer 120. In some aspects, the thickness of the bottom portion of the Ta(N) layer 120 (i.e., the portion of the Ta(N) layer 120 at the bottom of the via) is less than 1 nm. In some aspects, the thickness of the bottom portion of the Ta(N) layer 120 is approximately 0.5 nm. In some aspects, the thickness of the bottom portion of the Ta(N) layer 120 is between 0.5 nm and 0.7 nm. In some aspects, the thickness of the bottom portion of the Ta(N) layer 120 is between 0.4 nm and 0.8 nm.

FIG. 3G illustrates the result after a CVD deposition of a liner 122. In some aspects, the liner 122 comprises cobalt. In some aspects, the liner 122 comprises ruthenium. In some aspects, the liner 122 comprises binary Co—Ru. In some aspects, the thickness of the liner 122 is approximately 2.5 nm.

FIG. 3H illustrates the result after a copper plating step and a chemical/mechanical polishing (CMP) step that results in the completed via 202 that is filled with copper 124.

The improved via 202 provides several improvements over the conventional via 102. For example, the resistance of via 202 is 10-20% less than the resistance of the conventional via 102, and this can translate into a block-level maximum frequency gain of 1-2%. Moreover, process reliability is improved because the additional metal layer 204 covers the adhesion weak points at the bottom of the via. In some aspects, the additional metal layer 204 may be grown very thick (e.g., between 1-10 nm), which allows the thickness of the Ta(N) layer 120 to be significantly reduced without negatively affecting the adhesion of the via 202 and thus improving process reliability.

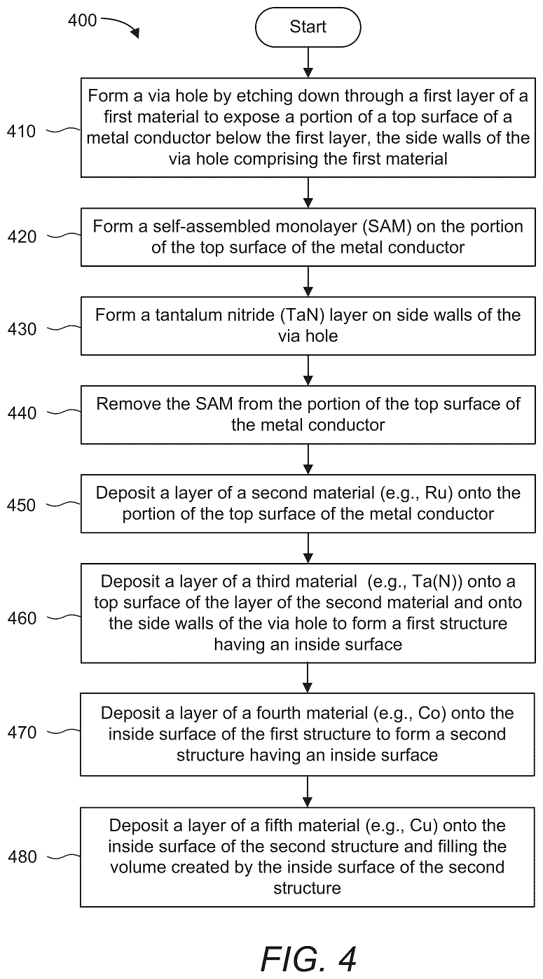

FIG. 4 is a flowchart of an example process 400 associated with fabrication of an improved via with a modified reverse selective barrier structure according to aspects of the disclosure.

As shown in FIG. 4, process 400 may include, at block 410, forming a via hole by etching down through a first layer of a first material to expose a portion of a top surface of a metal conductor below the first layer. In some aspects, the first layer comprises at least one of a dielectric layer, an oxide layer, or a passivation layer. In some aspects, the metal conductor below the first layer comprises copper.

As further shown in FIG. 4, process 400 may include, at block 420, forming a self-assembled monolayer (SAM) on the portion of the top surface of the metal conductor.

As further shown in FIG. 4, process 400 may include, at block 430, forming a tantalum nitride (TaN) layer on side walls of the via hole. In some aspects, forming the TaN layer comprises forming the TaN layer using an atomic layer deposition process.

As further shown in FIG. 4, process 400 may include, at block 440, removing the SAM from the portion of the top surface of the metal conductor. In some aspects, removing the SAM comprises removing the SAM using plasma ashing or thermal desorption.

As further shown in FIG. 4, process 400 may include, at block 450, depositing a layer of a second material onto the portion of the top surface of the metal conductor. In some aspects, the second material comprises at least one of ruthenium, molybdenum, osmium, iridium, rhodium, or a combination thereof. In some aspects, depositing the layer of the second material comprises depositing the layer of the second material using a selective deposition process.

As further shown in FIG. 4, process 400 may include, at block 460, depositing a layer of a third material onto a top surface of the layer of the second material and onto the side walls of the via hole to form a first structure having an inside surface. In some aspects, the third material comprises metallic tantalum. In some aspects, the metallic tantalum includes trace amounts of TaN. In some aspects, depositing the layer of the third material comprises depositing the layer of the third material using a physical vapor deposition process.

As further shown in FIG. 4, process 400 may include, at block 470, depositing a layer of a fourth material onto the inside surface of the first structure to form a second structure having an inside surface. In some aspects, the fourth material comprises at least one of cobalt, ruthenium, or a combination thereof. In some aspects, depositing the layer of the fourth material comprises depositing the layer of the fourth material using a physical vapor deposition process or a chemical vapor deposition process.

As further shown in FIG. 4, process 400 may include, at block 480, depositing a layer of a fifth material onto the inside surface of the second structure and filling the volume created by the inside surface of the second structure with the fifth material. In some aspects, the fifth material comprises copper. In some aspects, depositing the layer of the fifth material comprises depositing the layer of the fifth material using a plating process.

In some aspects, process 400 may include performing a planarization process to planarize the top surface of the fifth material. In some aspects, the planarization process comprises a CMP process.

Process 400 may include additional implementations, such as any single implementation or any combination of implementations described below and/or in connection with one or more other processes described elsewhere herein. Although FIG. 4 shows example blocks of process 400, in some implementations, process 400 may include additional blocks, fewer blocks, different blocks, or differently arranged blocks than those depicted in FIG. 4. Additionally, or alternatively, two or more of the blocks of process 400 may be performed in parallel.

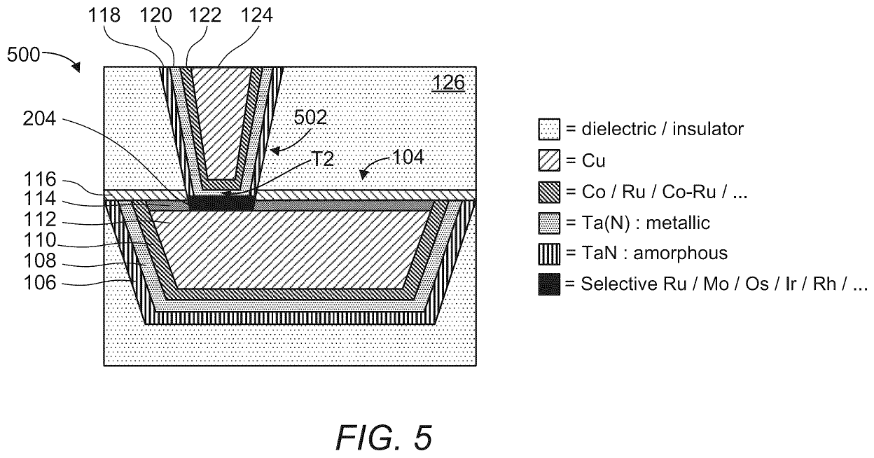

FIG. 5 is a cross-sectional view 500 of an improved via with a modified reverse selective barrier structure according to other aspects of the disclosure. The via 502 shown in FIG. 5 differs from the via 202 shown in FIG. 2 in that only the metal layer 204 is in contact with the copper structure 112, i.e., the amorphous TaN layer 118 does not extend down to the copper structure 112. In some aspects, the metal layer 204 comprises at least one of ruthenium (Ru), molybdenum (Mo), osmium (Os), iridium (Ir), or rhodium (Rh). This metal layer 204 provides good adhesion and allows the Ta(N) layer 120 to be thinner (e.g., 0.5-0.7 nm for the via 502 versus 1.0 nm for the via 102), which reduces the resistance of the via 502.

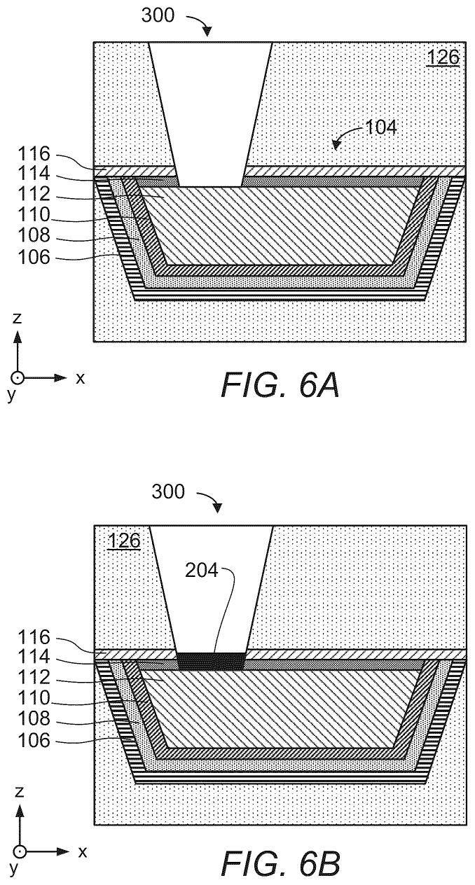

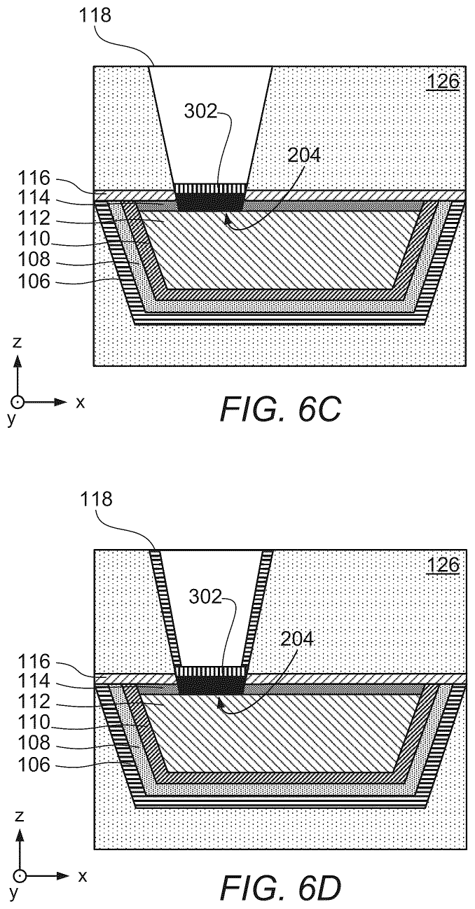

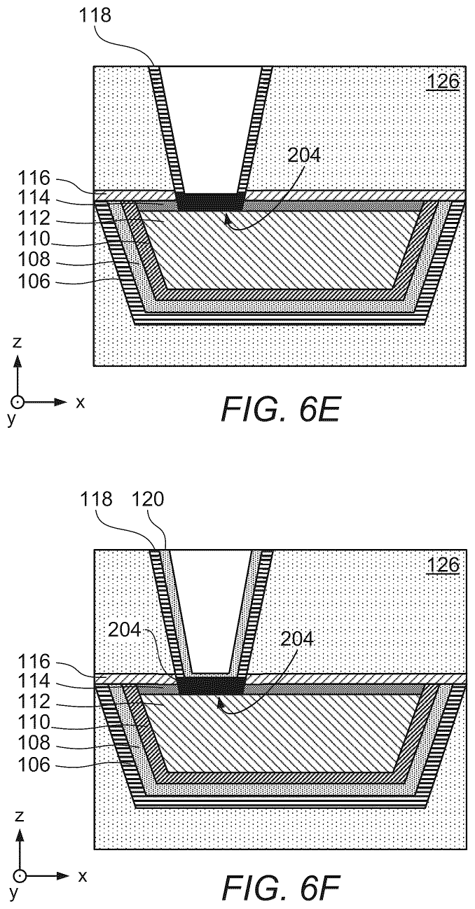

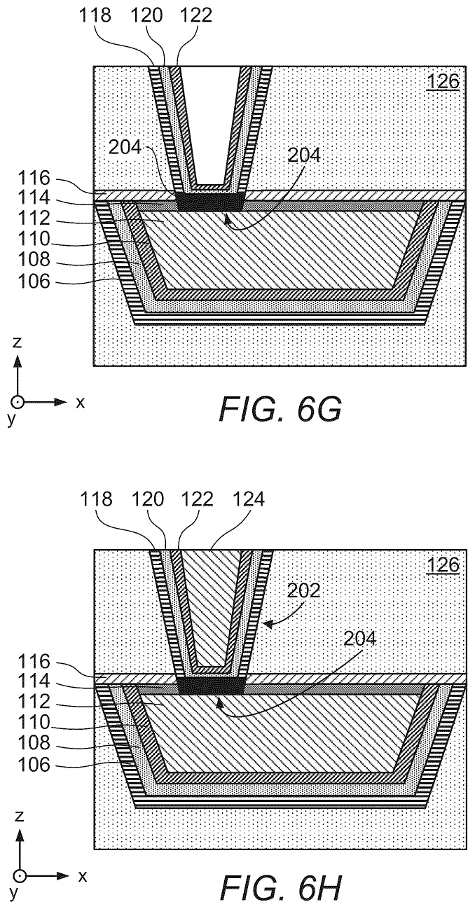

FIGS. 6A-6H are cross-sections that illustrate steps in a process for fabricating an improved via with a modified reverse selective barrier structure according to aspects of the disclosure, where the descriptions of like numbered components first appearing in earlier figures (e.g., 104-124, 204, 300, 302, etc.) will not be repeated here.

FIG. 6A illustrates the result after an etching process that produces a via hole 300 that exposes the copper structure 112. In some aspects, this process is part of a dual damascene trench/via patterning up to the step that removes the Co cap and exposes the Cu.

FIG. 6B illustrates the result after a selective deposit of a metal layer 204 onto the exposed portion of the copper structure 112. In some aspects, the thickness of the additional metal layer 204 is between 1 nm and 10 nm. In some aspects, the additional metal layer 204 comprises at least one of Ru, Mo, Os, Ir, or Rh. In some aspects, the resistivity of the additional metal layer 204 is less than 10 μΩ cm. In some aspects, the resistivity of the additional metal layer 204 is approximately 7.1 μΩ cm.

FIG. 6C illustrates the result after forming a self-assembled monolayer (SAM) 302 onto the metal layer 204.

FIG. 6D illustrates the result after an ALD process that deposits TaN on the sidewalls of the via hole 300 to produce the TaN layer 118. In some aspects, the ALD process causes the TaN layer 118 to encroach upon and/or displace some of the SAM 302 adjacent to the TaN layer 118.

FIG. 6E illustrates the result after a process to remove the SAM 302, e.g., via H2/N2 (plasma) ash or thermal desorption, to expose the metal layer 204.

FIG. 6F illustrates the result after a PVD deposition of Ta, resulting in a Ta(N) layer 120. In some aspects, the thickness of the bottom portion of the Ta(N) layer 120 (i.e., the portion of the Ta(N) layer 120 at the bottom of the via) is less than 1 nm. In some aspects, the thickness of the bottom portion of the Ta(N) layer 120 is approximately 0.5 nm. In some aspects, the thickness of the bottom portion of the Ta(N) layer 120 is between 0.5 nm and 0.7 nm. In some aspects, the thickness of the bottom portion of the Ta(N) layer 120 is between 0.4 nm and 0.8 nm.

FIG. 6G illustrates the result after a CVD deposition of a liner 122. In some aspects, the liner 122 comprises cobalt. In some aspects, the liner 122 comprises ruthenium. In some aspects, the liner 122 comprises binary Co—Ru. In some aspects, the thickness of the liner 122 is approximately 2.5 nm.

FIG. 6H illustrates the result after a copper plating step and a chemical/mechanical polishing (CMP) step that results in the completed via 202 that is filled with copper 124.

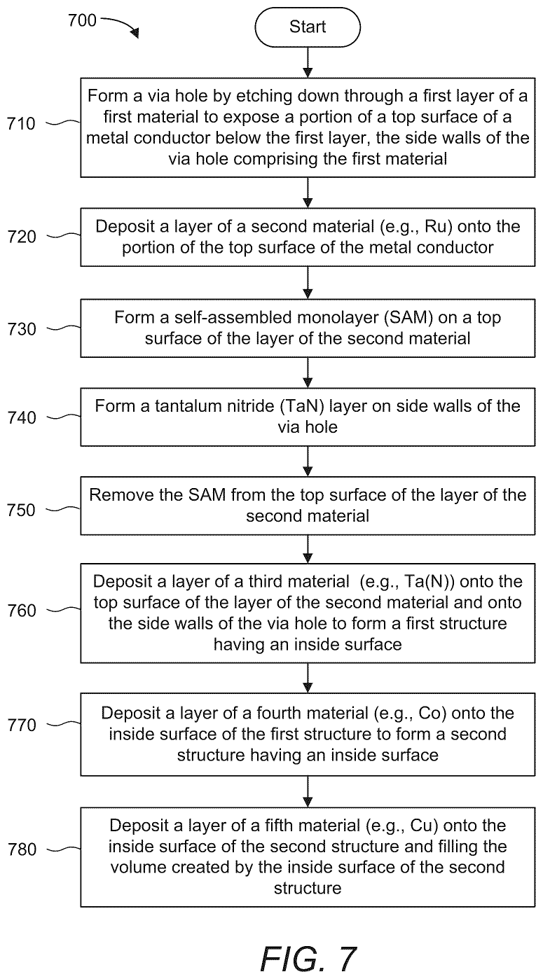

FIG. 7 is a flowchart of an example process 700 associated with fabrication of an improved via with a modified reverse selective barrier structure according to aspects of the disclosure.

As shown in FIG. 7, process 700 may include, at block 710, forming a via hole by etching down through a first layer of a first material to expose a portion of a top surface of a metal conductor below the first layer. In some aspects, the first layer comprises at least one of a dielectric layer, an oxide layer, or a passivation layer. In some aspects, the metal conductor below the first layer comprises copper.

As further shown in FIG. 7, process 700 may include, at block 720, depositing a layer of a second material onto the portion of the top surface of the metal conductor. In some aspects, the second material comprises at least one of ruthenium, molybdenum, osmium, iridium, rhodium, or a combination thereof. In some aspects, depositing the layer of the second material comprises depositing the layer of the second material using a selective deposition process.

As further shown in FIG. 7, process 700 may include, at block 730, forming a self-assembled monolayer (SAM) on the top surface of the second material.

As further shown in FIG. 7, process 700 may include, at block 740, forming a tantalum nitride (TaN) layer on side walls of the via hole. In some aspects, forming the TaN layer comprises forming the TaN layer using an atomic layer deposition process.

As further shown in FIG. 7, process 700 may include, at block 750, removing the SAM from the portion of the top surface of the second material. In some aspects, removing the SAM comprises removing the SAM using plasma ashing or thermal desorption.

As further shown in FIG. 7, process 700 may include, at block 760, depositing a layer of a third material onto a top surface of the layer of the second material and onto the side walls of the via hole to form a first structure having an inside surface. In some aspects, the third material comprises metallic tantalum. In some aspects, the metallic tantalum includes trace amounts of TaN. In some aspects, depositing the layer of the third material comprises depositing the layer of the third material using a physical vapor deposition process.

As further shown in FIG. 7, process 700 may include, at block 770, depositing a layer of a fourth material onto the inside surface of the first structure to form a second structure having an inside surface. In some aspects, the fourth material comprises at least one of cobalt, ruthenium, or a combination thereof. In some aspects, depositing the layer of the fourth material comprises depositing the layer of the fourth material using a physical vapor deposition process or a chemical vapor deposition process.

As further shown in FIG. 7, process 700 may include, at block 780, depositing a layer of a fifth material onto the inside surface of the second structure and filling the volume created by the inside surface of the second structure with the fifth material. In some aspects, the fifth material comprises copper. In some aspects, depositing the layer of the fifth material comprises depositing the layer of the fifth material using a plating process.

In some aspects, process 700 may include performing a planarization process to planarize the top surface of the fifth material. In some aspects, the planarization process comprises a CMP process.

Process 700 may include additional implementations, such as any single implementation or any combination of implementations described below and/or in connection with one or more other processes described elsewhere herein. Although FIG. 7 shows example blocks of process 700, in some implementations, process 700 may include additional blocks, fewer blocks, different blocks, or differently arranged blocks than those depicted in FIG. 7. Additionally, or alternatively, two or more of the blocks of process 700 may be performed in parallel.

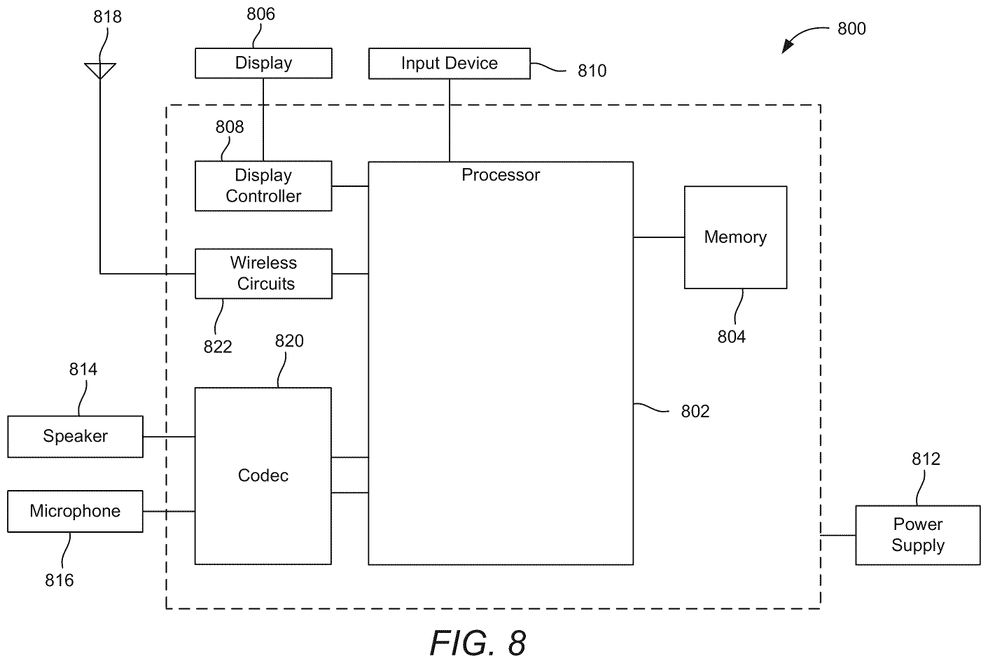

FIG. 8 illustrates a mobile device 800, according to aspects of the disclosure. In some aspects, the mobile device 800 may be implemented by including one or more IC devices manufactured based on the examples described in this disclosure.

In some aspects, mobile device 800 may be configured as a wireless communication device. As shown, mobile device 800 includes processor 802. Processor 802 may be communicatively coupled to memory 804 over a link, which may be a die-to-die or chip-to-chip link. Mobile device 800 also includes display 806 and display controller 808, with display controller 808 coupled to processor 802 and to display 806. The mobile device 800 may include input device 810 (e.g., physical, or virtual keyboard), power supply 812 (e.g., battery), speaker 814, microphone 816, and wireless antenna 818. In some aspects, the power supply 812 may directly or indirectly provide the supply voltage for operating some or all of the components of the mobile device 800.

In some aspects, FIG. 8 may include coder/decoder (CODEC) 820 (e.g., an audio and/or voice CODEC) coupled to processor 802; speaker 814 and microphone 816 coupled to CODEC 820; and wireless circuits 822 (which may include a modem, RF circuitry, filters, etc.) coupled to wireless antenna 818 and to processor 802.

In some aspects, one or more of processor 802, display controller 808, memory 804, CODEC 820, and wireless circuits 822 may include one or more IC devices including semiconductor structures manufactured according to the examples described in this disclosure.

It should be noted that although FIG. 8 depicts a mobile device 800, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

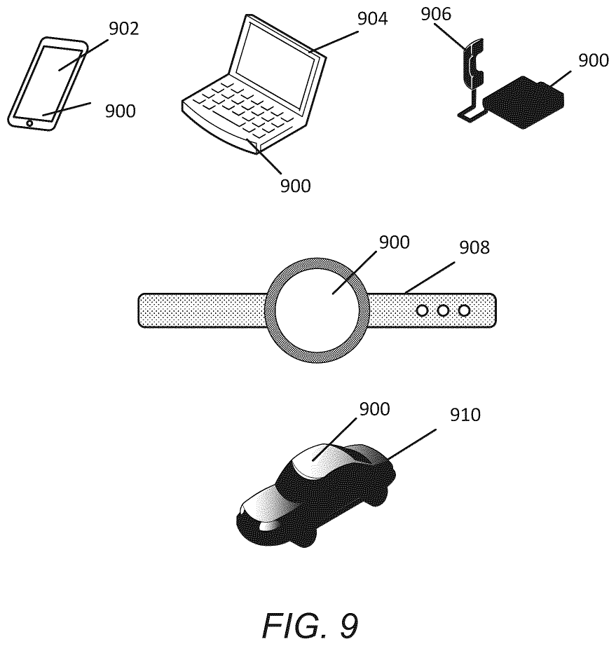

FIG. 9 illustrates various electronic devices that may be integrated with any of the aforementioned devices, semiconductor devices, integrated circuit (IC) packages, integrated circuit (IC) devices, semiconductor devices, integrated circuits, electronic components, interposer packages, package-on-package (POP), System in Package (SiP), or System on Chip (SoC). For example, a mobile phone device 902, a laptop computer device 904, a fixed location terminal device 906, a wearable device 908, or automotive vehicle 910 may include a semiconductor device 900 (e.g., the semiconductor devices shown in cross section in FIG. 2 and FIG. 5) as described herein. The devices 902, 904, 906 and 908 and the vehicle 910 illustrated in FIG. 9 are merely exemplary. Other apparatuses or devices may also feature the semiconductor device 900 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. A via structure, comprising: a first metal structure providing an electrical conductor oriented vertically; a second structure surrounding and in contact with a bottom and sides of the first metal structure; a third structure surrounding and in contact with a bottom and sides of the second structure; a fourth structure disposed beneath and in contact with a bottom of the third structure; and a fifth structure surrounding and in contact with sides of the third structure, wherein a bottom surface of the fourth structure is in contact with a top surface of a metallization layer disposed below the via structure.

Clause 2. The via structure of clause 1, wherein the fifth structure also surrounds and is in contact with sides of the fourth structure.

Clause 3. The via structure of any of clauses 1 to 2, wherein the first metal structure comprises copper.

Clause 4. The via structure of any of clauses 1 to 3, wherein the second structure comprises at least one of cobalt, ruthenium, or a combination thereof.

Clause 5. The via structure of any of clauses 1 to 4, wherein the third structure comprises metallic tantalum.

Clause 6. The via structure of any of clauses 1 to 5, wherein the fourth structure comprises at least one of ruthenium, molybdenum, osmium, iridium, rhodium, or a combination thereof.

Clause 7. The via structure of any of clauses 1 to 6, wherein the fifth structure comprises amorphous tantalum nitride.

Clause 8. The via structure of any of clauses 1 to 7, wherein the metallization layer comprises copper.

Clause 9. The via structure of any of clauses 1 to 8, wherein a top surface of the first metal structure is in contact with a bottom surface of a second metallization layer.

Clause 10. A method of fabricating a via structure, the method comprising: forming a via hole by etching down through a first layer of a first material to expose a portion of a top surface of a metal conductor below the first layer; forming a self-assembled monolayer (SAM) on the portion of the top surface of the metal conductor; forming a tantalum nitride (TaN) layer on side walls of the via hole; removing the SAM from the portion of the top surface of the metal conductor; depositing a layer of a second material onto the portion of the top surface of the metal conductor; depositing a layer of a third material onto a top surface of the layer of the second material and onto the side walls of the via hole to form a first structure having an inside surface; depositing a layer of a fourth material onto the inside surface of the first structure to form a second structure having an inside surface; and depositing a layer of a fifth material onto the inside surface of the second structure and filling a volume created by the inside surface of the second structure.

Clause 11. The method of clause 10, wherein the first layer comprises at least one of a dielectric layer, an oxide layer, or a passivation layer.

Clause 12. The method of any of clauses 10 to 11, wherein the metal conductor below the first layer comprises copper.

Clause 13. The method of any of clauses 10 to 12, wherein forming the TaN layer comprises forming the TaN layer using an atomic layer deposition process.

Clause 14. The method of any of clauses 10 to 13, wherein removing the SAM comprises removing the SAM using plasma ashing or thermal desorption.

Clause 15. The method of any of clauses 10 to 14, wherein the second material comprises at least one of ruthenium, molybdenum, osmium, iridium, rhodium, or a combination thereof.

Clause 16. The method of any of clauses 10 to 15, wherein depositing the layer of the second material comprises depositing the layer of the second material using a selective deposition process.

Clause 17. The method of any of clauses 10 to 16, wherein the third material comprises metallic tantalum.

Clause 18. The method of any of clauses 10 to 17, wherein depositing the layer of the third material comprises depositing the layer of the third material using a physical vapor deposition process.

Clause 19. The method of any of clauses 10 to 18, wherein the fourth material comprises at least one of cobalt, ruthenium, or a combination thereof.

Clause 20. The method of any of clauses 10 to 19, wherein depositing the layer of the fourth material comprises depositing the layer of the fourth material using a physical vapor deposition process or a chemical vapor deposition process.

Clause 21. The method of any of clauses 10 to 20, wherein the fifth material comprises copper.

Clause 22. The method of any of clauses 10 to 21, wherein depositing the layer of the fifth material comprises depositing the layer of the fifth material using a plating process.

Clause 23. The method of any of clauses 10 to 22, further comprising performing a planarization process to planarize a top surface of the fifth material.

Clause 24. The method of clause 23, wherein performing the planarization process comprises performing a chemical/mechanical planarization process.

Clause 25. A method of fabricating a via structure, the method comprising: forming a via hole by etching down through a first layer of a first material to expose a portion of a top surface of a metal conductor below the first layer; depositing a layer of a second material onto the portion of the top surface of the metal conductor; forming a self-assembled monolayer (SAM) on a top surface of the layer of the second material; forming a tantalum nitride (TaN) layer on side walls of the via hole; removing the SAM from the top surface of the layer of the second material; depositing a layer of a third material onto the top surface of the layer of the second material and onto the side walls of the via hole to form a first structure having an inside surface; depositing a layer of a fourth material onto the inside surface of the first structure to form a second structure having an inside surface; and depositing a layer of a fifth material onto the inside surface of the second structure and filling a volume created by the inside surface of the second structure.

Clause 26. The method of clause 25, wherein the first layer comprises at least one of a dielectric layer, an oxide layer, or a passivation layer.

Clause 27. The method of any of clauses 25 to 26, wherein the metal conductor below the first layer comprises copper.

Clause 28. The method of any of clauses 25 to 27, wherein forming the TaN layer comprises forming the TaN layer using an atomic layer deposition process.

Clause 29. The method of any of clauses 25 to 28, wherein removing the SAM comprises removing the SAM using plasma ashing or thermal desorption.

Clause 30. The method of any of clauses 25 to 29, wherein the second material comprises at least one of ruthenium, molybdenum, osmium, iridium, rhodium, or a combination thereof.

Clause 31. The method of any of clauses 25 to 30, wherein depositing the layer of the second material comprises depositing the layer of the second material using a selective deposition process.

Clause 32. The method of any of clauses 25 to 31, wherein the third material comprises metallic tantalum.

Clause 33. The method of any of clauses 25 to 32, wherein depositing the layer of the third material comprises depositing the layer of the third material using a physical vapor deposition process.

Clause 34. The method of any of clauses 25 to 33, wherein the fourth material comprises at least one of cobalt, ruthenium, or a combination thereof.

Clause 35. The method of any of clauses 25 to 34, wherein depositing the layer of the fourth material comprises depositing the layer of the fourth material using a physical vapor deposition process or a chemical vapor deposition process.

Clause 36. The method of any of clauses 25 to 35, wherein the fifth material comprises copper.

Clause 37. The method of any of clauses 25 to 36, wherein depositing the layer of the fifth material comprises depositing the layer of the fifth material using a plating process.

Clause 38. The method of any of clauses 25 to 37, further comprising performing a planarization process to planarize a top surface of the fifth material.

Clause 39. The method of clause 38, wherein performing the planarization process comprises performing a chemical/mechanical planarization process.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general-purpose processor, a DSP, an ASIC, an FPGA, or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., a user equipment (UE), mobile phone, mobile terminal). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A via structure, comprising:
a first metal structure providing an electrical conductor oriented vertically;
a second structure surrounding and in contact with a bottom and sides of the first metal structure;
a third structure surrounding and in contact with a bottom and sides of the second structure;
a fourth structure disposed beneath and in contact with a bottom of the third structure; and
a fifth structure surrounding and in contact with sides of the third structure,
wherein a bottom surface of the fourth structure is in contact with a top surface of a metallization layer disposed below the via structure.

2. The via structure of claim 1, wherein the fifth structure also surrounds and is in contact with sides of the fourth structure.

3. The via structure of claim 1, wherein the first metal structure comprises copper.

4. The via structure of claim 1, wherein the second structure comprises at least one of cobalt, ruthenium, or a combination thereof.

5. The via structure of claim 1, wherein the third structure comprises metallic tantalum.

6. The via structure of claim 1, wherein the fourth structure comprises at least one of ruthenium, molybdenum, osmium, iridium, rhodium, or a combination thereof.

7. The via structure of claim 1, wherein the fifth structure comprises amorphous tantalum nitride.

8. The via structure of claim 1, wherein the metallization layer comprises copper.

9. The via structure of claim 1, wherein a top surface of the first metal structure is in contact with a bottom surface of a second metallization layer.

10. A method of fabricating a via structure, the method comprising:
forming a via hole by etching down through a first layer of a first material to expose a portion of a top surface of a metal conductor below the first layer;
forming a self-assembled monolayer (SAM) on the portion of the top surface of the metal conductor;
forming a tantalum nitride (TaN) layer on side walls of the via hole;
removing the SAM from the portion of the top surface of the metal conductor;
depositing a layer of a second material onto the portion of the top surface of the metal conductor;
depositing a layer of a third material onto a top surface of the layer of the second material and onto the side walls of the via hole to form a first structure having an inside surface;
depositing a layer of a fourth material onto the inside surface of the first structure to form a second structure having an inside surface; and
depositing a layer of a fifth material onto the inside surface of the second structure and filling a volume created by the inside surface of the second structure.

11. The method of claim 10, wherein the first layer comprises at least one of a dielectric layer, an oxide layer, or a passivation layer.

12. The method of claim 10, wherein the metal conductor below the first layer comprises copper.

13. The method of claim 10, wherein forming the TaN layer comprises forming the TaN layer using an atomic layer deposition process.

14. The method of claim 10, wherein removing the SAM comprises removing the SAM using plasma ashing or thermal desorption.

15. The method of claim 10, wherein the second material comprises at least one of ruthenium, molybdenum, osmium, iridium, rhodium, or a combination thereof.

16. The method of claim 10, wherein depositing the layer of the second material comprises depositing the layer of the second material using a selective deposition process.

17. The method of claim 10, wherein the third material comprises metallic tantalum.

18. The method of claim 10, wherein depositing the layer of the third material comprises depositing the layer of the third material using a physical vapor deposition process.

19. The method of claim 10, wherein the fourth material comprises at least one of cobalt, ruthenium, or a combination thereof.

20. The method of claim 10, wherein depositing the layer of the fourth material comprises depositing the layer of the fourth material using a physical vapor deposition process or a chemical vapor deposition process.

21. The method of claim 10, wherein the fifth material comprises copper.

22. The method of claim 10, wherein depositing the layer of the fifth material comprises depositing the layer of the fifth material using a plating process.

23. The method of claim 10, further comprising performing a planarization process to planarize a top surface of the fifth material.

24. The method of claim 23, wherein performing the planarization process comprises performing a chemical/mechanical planarization process.

25. A method of fabricating a via structure, the method comprising:
forming a via hole by etching down through a first layer of a first material to expose a portion of a top surface of a metal conductor below the first layer;
depositing a layer of a second material onto the portion of the top surface of the metal conductor;
forming a self-assembled monolayer (SAM) on a top surface of the layer of the second material;
forming a tantalum nitride (TaN) layer on side walls of the via hole;
removing the SAM from the top surface of the layer of the second material;
depositing a layer of a third material onto the top surface of the layer of the second material and onto the side walls of the via hole to form a first structure having an inside surface;
depositing a layer of a fourth material onto the inside surface of the first structure to form a second structure having an inside surface; and
depositing a layer of a fifth material onto the inside surface of the second structure and filling a volume created by the inside surface of the second structure.

26. The method of claim 25, wherein the first layer comprises at least one of a dielectric layer, an oxide layer, or a passivation layer.

27. The method of claim 25, wherein the metal conductor below the first layer comprises copper.

28. The method of claim 25, wherein forming the TaN layer comprises forming the TaN layer using an atomic layer deposition process.

29. The method of claim 25, wherein removing the SAM comprises removing the SAM using plasma ashing or thermal desorption.

30. The method of claim 25, wherein the second material comprises at least one of ruthenium, molybdenum, osmium, iridium, rhodium, or a combination thereof.

31. The method of claim 25, wherein depositing the layer of the second material comprises depositing the layer of the second material using a selective deposition process.

32. The method of claim 25, wherein the third material comprises metallic tantalum.

33. The method of claim 25, wherein depositing the layer of the third material comprises depositing the layer of the third material using a physical vapor deposition process.

34. The method of claim 25, wherein the fourth material comprises at least one of cobalt, ruthenium, or a combination thereof.

35. The method of claim 25, wherein depositing the layer of the fourth material comprises depositing the layer of the fourth material using a physical vapor deposition process or a chemical vapor deposition process.

36. The method of claim 25, wherein the fifth material comprises copper.

37. The method of claim 25, wherein depositing the layer of the fifth material comprises depositing the layer of the fifth material using a plating process.

38. The method of claim 25, further comprising performing a planarization process to planarize a top surface of the fifth material.

39. The method of claim 38, wherein performing the planarization process comprises performing a chemical/mechanical planarization process.
